(19) United States
(12) Patent Application Publication
(10) Pub. No.: US 2025/0115197 A1
(43) Pub. Date: Apr. 10, 2025

(54) Method for Checking the On-Board Diagnostics Relevance of an Input Signal

(71) Applicant: Bayerische Motoren Werke Aktiengesellschaft, Muenchen (DE)

(72) Inventor: Sebastian Grasreiner, Miesbach (DE)

(21) Appl. No.: 18/835,966

(22) PCT Filed: Jan. 24, 2023
(86) PCT No.: PCT/EP2023/051717

§ 371 Date: Aug. 5, 2024

(30) Foreign Application Priority Data
Mar. 7, 2022 (DE) 10 2022 105 249.4

(51) Int. Cl. B60R 16/023; G07C 5/00

(52) U.S. Cl. CPC B60R 16/0232; G07C 5/008

(57) ABSTRACT

A method automatically checks, in an approval procedure for a vehicle, whether an input signal of a control unit for the vehicle is potentially relevant to on-board diagnostics. The method includes using a signal network which represents a signal flow in the control unit. The signal network includes the input signal and at least one on-board diagnostics-relevant output signal. The method also includesbverifying whether a signal connection is present between the input signal and the at least one on-board diagnostics-relevant output signal. The method further includes indicating that the input signal is potentially on-board diagnostics-relevant if the signal connection is present between the input signal and the at least one output signal.

The present application is the U.S. national phase of PCT Application PCT/EP2023/051717 filed on Jan. 24, 2023, which claims priority of German patent application no. 10 2022 105 249.4 filed on Mar. 7, 2022, the entire contents of which are incorporated herein by reference.

### TECHNICAL FIELD

The present disclosure relates generally to automatically checking whether an input signal of a control unit for a vehicle is potentially relevant to on-board diagnostics.

### BACKGROUND

Modern motor vehicles use a plurality of control units which are connected to one another. Some signals transmitted in the vehicle's on-board network may have an impact on the emissions of the vehicle. Therefore, the signal characteristics of these signals must be disclosed when vehicles are submitted for approval.

In the following, important signal properties are summarized under the term on-board diagnostics (OBD) properties. In this vehicle diagnostic system, the signals of any devices influencing exhaust gases can be monitored during driving operation. Any faults are indicated to the driver by an indicator light and stored in the respective control unit. Error messages can be queried, e.g. during the vehicle service. In the vehicle approval process, it is necessary to demonstrate that relevant signals are OBD-compliant, i.e. that monitoring these signals meets legal requirements.

One difficulty in demonstrating this can be the enormous complexity of modern on-board networks with a plurality of control units (ECU), which are often designed and manufactured by different companies. Distributed systems with thousands of interacting signals and millions of signal connections may need to be checked for OBD compliance. Consequently, it can be very difficult in such complex systems to demonstrate or find out which of the input signals have an effect on OBD compliance at all, i.e. which of the input signals are OBD-relevant. The term OBD compliance can be understood to mean that a signal is monitored in accordance with specific legislation with regard to a malfunction that can lead to degraded emissions. Accordingly, OBD-relevant input signals are understood to mean signals that have to implement a legally required OBD compliance. OBD relevance (in terms of the “use of the signal”) is a signal property that requires monitoring. If the signals are monitored in an OBD-compliant manner (with regard to the “provision of the signal”), then the requirement fits the implementation. It is therefore useful to have information about the OBD relevance of the existing input signals. However, obtaining this information can be very time-consuming.

There is a need, therefore, for allowing for simpler checking of whether an input signal of a control unit is OBD-relevant, even in complex systems.

### SUMMARY

The above-discussed need, as well as others, are achieved according to at least some of the embodiments disclosed and claimed herein. Further advantageous embodiments are described in the dependent patent claims, the following description, and in connection with the figures.

Accordingly, a method is proposed for automatically checking, in an approval procedure for a vehicle, whether an input signal (or a plurality of input signals) of a control unit for the vehicle is potentially relevant to on-board diagnostics. An input signal can be a signal at the beginning of a signal chain, e.g. a bus signal (In-Bus) received at the control unit, a sensor signal (In-Sensor) received at the control unit, or else an internal signal from the control unit. The method comprises using a signal network (e.g. graphical signal network or other network representation with a sufficiently high degree of detail), which represents a signal flow in the control unit, comprising the input signal and at least one on-board diagnostics-relevant output signal. The method comprises verifying whether a signal connection is present between the input signal to be evaluated and the at least one on-board diagnostics-relevant signal, in particular output signal (e.g. either output signal or ECU-internal; an output signal can be a signal at the end of a signal chain, e.g. a bus signal (Out-Bus) that is output by the control unit, an actuator signal (Out-Actuator) that is output by the control unit, or even an internal signal of the control unit itself if this is treated as the last element of the signal chain), and further, indicating that the input signal is potentially on-board diagnostics-relevant if a signal connection is present between the input signal and the at least one output signal. For example, based on this, an optional step can be used to check (e.g. manually) whether the input signal is also actually OBD-relevant.

The method can be carried out outside the vehicle, e.g. in a purely virtual software environment. In particular, it is provided that the method is not carried out using real control units and/or sensors of the vehicle, but instead, for example, a simulated signal network is used. The content of the input signal to be checked is not relevant according to the method, but only whether said input signal could or could not have OBD relevance due to a specific signal connection. According to the proposed method, it is sufficient to check the OBD relevance in a software environment (e.g. software relationships are analyzed). For this purpose, no signal contents are analyzed but only signal paths, and these are used to evaluate signal classes (e.g. Class I “OBD-relevant Yes”; Class II “OBD-relevant No”). No sensor is required for this, no real control unit is required and no signal content is required. For the approval of a vehicle it may be necessary to demonstrate which signals of the vehicle are OBD-relevant, which according to the method can be carried out e.g. based on software before the approval or commissioning of the actual vehicle.

The method can be advantageous, because now not all of the input signals need to be more accurately checked (e.g. in a manual process), rather only those which are automatically indicated as being potentially OBD-relevant. Input signals that are indicated as non-OBD-relevant on the other hand can, for example, be ignored. This makes it much easier to carry out a test procedure, especially in highly complex systems, since the manual pre-testing of a large number of signal sources can be dispensed with. For example, the input signal can be a sensor signal that is applied to a signal input of the control unit. Alternatively or in addition, the input signal (or a further input signal) may be a BUS signal that is applied to a signal input of the control unit. For example, the at least one output signal (or even a plurality of output signals) is a signal that is output to a BUS line connected to the control unit. It can be an Out-Bus signal or else an Out-Act signal (actuator signal), which is available as an endpoint in the connection query. In the case of OBD relevance, the input signal is evaluated in relation to the “OBD-known” output signal. Advantageously, according to the method a plurality of input signals, e.g. of multiple control units, are checked for their potential OBD relevance. This allows for a particularly efficient test procedure.

Accordingly, according to one exemplary embodiment, a plurality of input signals are checked with regard to their respective potential relevance to on-board diagnostics, wherein the indication comprises which of the plurality of input signals are potentially on-board diagnostics-relevant. Optionally, when verifying whether a signal connection exists between the input signal and the at least one on-board diagnostics-relevant output signal, a connection matrix is used. This enables an efficient and structured check, especially when checking a large number of input signals.

Aspects of the disclosure further relate to a control mechanism to better classify the validity of the test result according to the method. To do this, the test result (i.e. whether an input signal is indicated as potentially OBD-relevant) is verified using a comparison value or reference value.

According to one aspect, the method further comprises the steps of—providing a pre-determined property of the input signal with regard to its relevance to on-board diagnostics (this can be done, for example, in a reference list, which can be advantageously used for very large quantities of input signals in complex systems); —comparing the automatically determined potentially on-board diagnostics-relevant input signal with the pre-determined property; the comparison step can be carried out, for example, by comparing entries in the reference list with values determined according to the method with regard to the potential OBD relevance of the input signal; and—outputting a warning signal if the automatically determined, potential relevance to on-board diagnostics does not match the previously determined property of the input signal.

In other words, a consistency check of the test result can be performed according to method 10. For example, this can refer to historical documentation values that can be provided in the reference list. This enables a mutual verification of the test results according to the method, as well as the attributes of the input signals used previously, for example. In the event that a warning signal is output due to a detected inconsistency in the attributes or values, the affected input signal specifically can advantageously be checked, so that the method can be monitored or validated in a focused and efficient manner.

According to a further aspect relating to consistency checking, the method further comprises: —checking whether the input signal is sent from an additional control unit for the vehicle as an output signal (e.g. to the signal input of the affected control unit); —automatically checking whether the output signal from the additional control unit is indicated as on-board diagnostics-monitored (e.g. the OBD compliance of the output signal of the additional control unit can be monitored); and—outputting a warning signal if the on-board diagnostic property of the input signal and the output signal, as verified by both control units, are inconsistent.

In the case of control units connected in series, the output signal of one control unit corresponds to the input signal of the other control unit. In this case, if the input signal is OBD-relevant, then the output signal must also be OBD-monitored (OBD-compliant). If this is not the case, an inconsistency can be detected in the automated comparison of the OBD attributes, which causes the warning signal to be output.

For example, the warning signal can be output if the input signal is indicated as OBD-relevant but the output signal is not OBD-compliant. This allows changes to be made, for example, in order to better comply with legal requirements regarding on-board diagnostics. For example, the method can also be used to optimize the control unit. Thus, in the event that the input signal is indicated as not OBD-relevant but the output signal is OBD-compliant, a warning can be issued that the system exceeds the requirements. Here, for example, the OBD monitoring of the output signal can be omitted in order to make the system more efficient and cost-effective.

Especially in highly complex systems it can be important to perform a consistent treatment of the OBD property of the signals throughout the entire signal flow. The proposed method can be advantageously used to ensure consistent treatment of OBD signals throughout the system.

Examples relate to a computer program that comprises program code to carry out a disclosed method when the computer program is executed on a processor, a computer, or programmable hardware. Such a computer program can advantageously be provided and implemented in the development and documentation of control devices.

The above-described features and advantages, as well as others, will become more readily apparent to those of ordinary skill in the art by reference to the following detailed description and accompanying drawings.

### BRIEF DESCRIPTION OF THE DRAWINGS

FIG. 1 shows a flowchart of a method for determining whether an input signal of a control unit is potentially OBD-relevant;

FIG. 2 shows an example of a signal network of a control unit;

FIG. 3a shows an example of OBD-relevance values of various input signals of the signal network determined by means of a connection matrix;

FIG. 3b shows another example of OBD-relevance values of various input signals of the signal network determined by means of a connection matrix;

FIG. 4 shows an exemplary comparison of OBD-relevance values determined according to the method with a reference list for sensors on the vehicle control unit; and

FIG. 5 shows an example of a comparison of OBD-relevant input signals with OBD information on corresponding output signals of an upstream control unit.

### DETAILED DESCRIPTION

Various exemplary embodiments will now be described in more detail with reference to the accompanying drawings, in which several exemplary embodiments are shown. In the figures, the thickness dimensions of lines, layers and/or regions are shown exaggerated for the sake of clarity. In the following description of the attached figures, which only show some exemplary embodiments, the same reference numerals can be used to designate identical or equivalent components.

Any element which is designated as being “connected” or “coupled” to any other element can either be directly connected or coupled to the other element or else intervening elements may be present. Unless otherwise defined, all of the terms used herein (including technical and scientific terms) have the same meanings as would be ascribed to them by an average person skilled in the art in the field to which the exemplary embodiments belong. The use of the female gender for reasons of gender-specific diversity does not exclude the possibility that male persons may also be referenced or meant. In particular, for the entire disclosure, a user can refer both to a male and a female user.

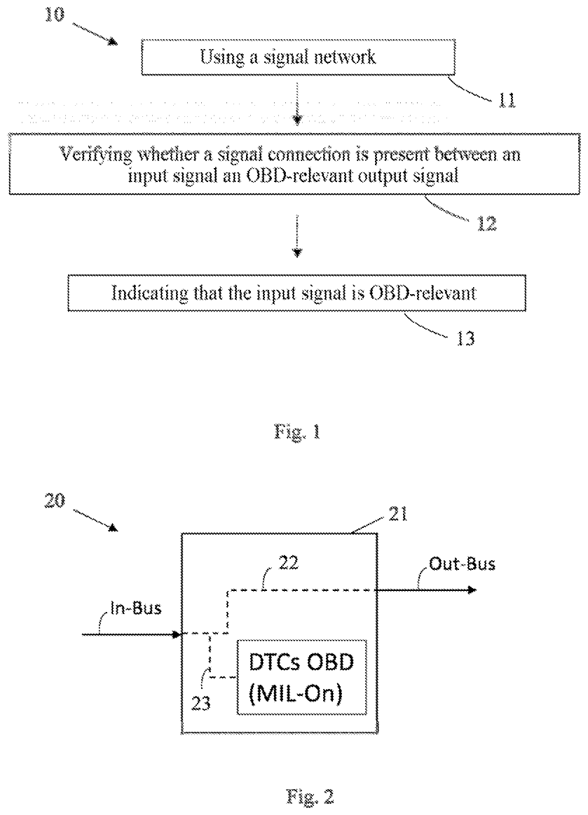

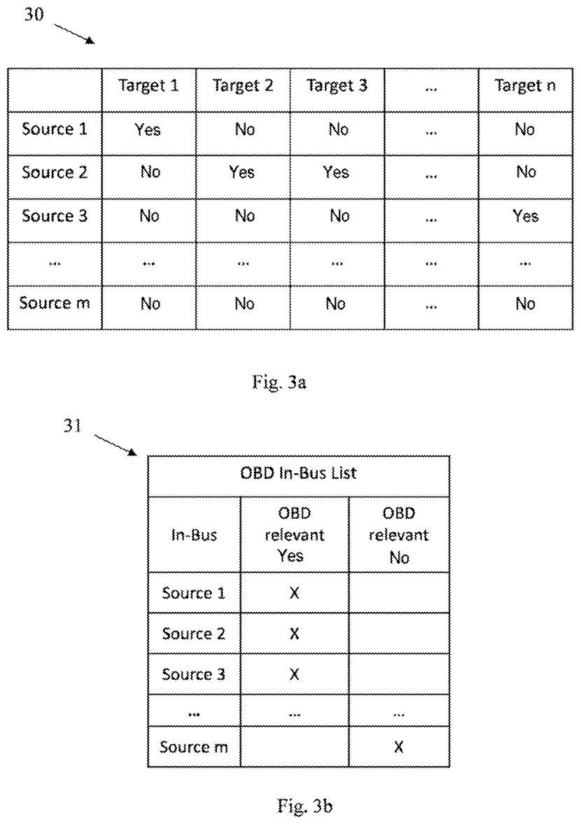

FIG. 1 shows a flowchart of a method 10 for determining whether an input signal of a control unit is potentially OBD-relevant. The method comprises the use 11 of a signal network, which represents a signal flow in the control unit. The signal network comprises at least the input signal (e.g. including a plurality of input signals) and at least one on-board diagnostics-relevant output signal (e.g. output signal or also ECU internal signal, e.g. DTCs OBD (MIL-On) shown in FIG. 2; or a plurality of such output signals, see also the table in FIG. 3a). A verification 12 is carried out as to whether a signal connection is present between the input signal and the at least one on-board diagnostics-relevant output signal, and an indication 13 that the input signal is potentially on-board diagnostics-relevant in the case that a signal connection is present between the input signal and the at least one output signal. A test procedure, e.g. for use in a vehicle approval process, is therefore proposed. In particular, the test procedure can be carried out purely in software.

If there is a signal connection present between the OBD-relevant output signal and the input signal, the input signal may have an effect on the OBD property of the output signal. If the input signal does affect the output signal (e.g. to a certain minimum degree), then the input signal is OBD-relevant. However, since not all connected input signals must have a significant influence, a potential OBD relevance of the input signal can be confirmed first. All potentially relevant input signals can then be examined in further steps to determine whether they are actually OBD-relevant or not. An advantage of this approach can be the fact that a pre-selection can be carried out in an automated procedure using the steps proposed here, so that, for example, significantly fewer input signals have to be checked manually with regard to their OBD relevance.

According to the method, for example, as part of the development and/or approval of the vehicle, a signal can be evaluated for its use in the signal network (e.g. source code), (e.g. where does the signal flow go to if the code is executed later). The content of the messages or signals is irrelevant to the proposed method. The signals can be evaluated with regard to OBD relevance for the approval, regardless of the signal content. The method works “offline”, i.e. outside of the actual vehicle. No control unit, no evaluation unit, no sensor is required, but only code or (virtual or simulated) signal networks that reflect the code behavior.

FIG. 2 shows an example of a signal network 20 of a control unit 21. An input signal In-Bus (e.g. bus signal/output signal of another control unit or else a sensor signal) is received at an input of the control unit 21. An output signal Out-Bus is output from a signal output of the control unit 21.

In the example shown, a signal connection 22 is present between the output signal Out-Bus and the input signal In-Bus. Therefore, if the output signal Out-Bus is OBD-relevant, the input signal In-Bus is also indicated as potentially OBD-relevant.

In addition, the control unit 21 has an internal memory in which, for example, error codes (e.g. diagnostic trouble codes DTC) can be stored. If such an error code is stored, a warning light can be switched on by the control unit (e.g. Malfunction indicating light MIL). A signal connection 23 is present between the fault memory and the input signal In-Bus. Since the entry in the fault memory has OBD relevance and a signal connection 23 to the input signal In-Bus exists, according to the method the input signal In-Bus is also indicated as potentially OBD-relevant for this reason (e.g. even if the control unit did not have a signal output). The connections 22 and 23 shown in FIG. 2 can occur together in any form of combination or in isolation and lead to potential OBD relevance of the evaluated input.

Further details and aspects are mentioned in conjunction with the examples described above or below. The exemplary embodiment shown in FIG. 2 may have one or more optional additional features corresponding to one or more aspects mentioned in connection with the proposed design or with one or more exemplary embodiments described above (e.g. FIG. 1) or below (e.g. FIGS. 3a-5).

FIGS. 3a, 3b show examples of OBD relevance values of various input signals of the signal network determined by means of a connection matrix 30. The indication 13 of whether or not the respective input signals are potentially OBD-relevant can be implemented by entries in an OBD In-Bus list 31.

The connection matrix 30 indicates exemplary signal connections between targets of the signal (Targets 1-n) and sources of the signal (Sources 1-m) in the signal network. The observed output signals can be determined in the same way for the signal targets Targets 1-n and the observed input signals come from the respective signal sources Sources 1-m.

For example, a signal connection exists from signal source Source 1 only to signal target Target 1. For example, a signal connection exists from signal source Source 2 only to signal targets Target 2 and Target 3.

For example, a signal connection exists from signal source Source 3 only to signal target Target n. For example, there is no signal connection at all from signal source Source m to signal targets Target 1-n.

The output signals for the Target 1-n signal targets are all assumed to be known OBD-relevant and have been included in the analysis of the connection matrix for precisely this reason. The input signals from the signal sources Source 1-m are only indicated as potentially OBD-relevant if a signal connection to at least one OBD-relevant output signal is present. Therefore, in this example, the input signals of all signal sources Source 1-3 are indicated in the list 30 as potentially OBD-relevant, whereas the input signal of the signal source Source m is indicated as not potentially OBD-relevant (and therefore not OBD-relevant at all).

The attribution is carried out as follows: if Source 1 has at least one connection to a Target 1-n, then Source 1 is also potentially OBD-relevant (Bool OR for source connection). Otherwise, not OBD-relevant in this query. In a computer code-like notation, the method 10 for determining whether input signals are potentially OBD-relevant can be expressed as follows:

```
For every In-Bus msg:
  - For every Out-Actuator (OBD Monitored):-if
  Connection 22 exists then In-Bus msg== “OBD
  relevant”; End For;
  - For every DTC OBD (MIL-On): if Connection 23
  exists then In-Bus msg== “OBD relevant”; End For;
  - If NOT In-Bus msg == “OBD relevant” then In-Bus
  msg== “not OBD relevant”;
End For.
```

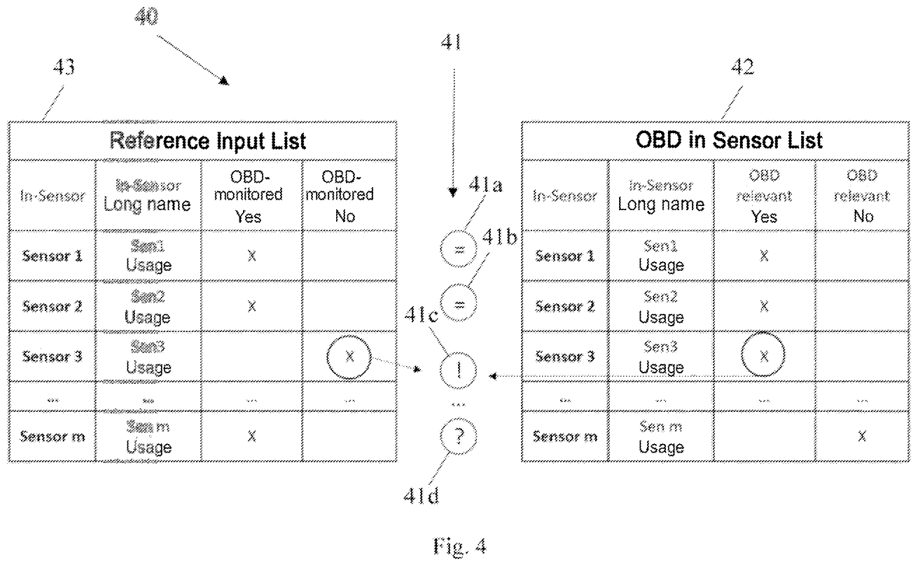

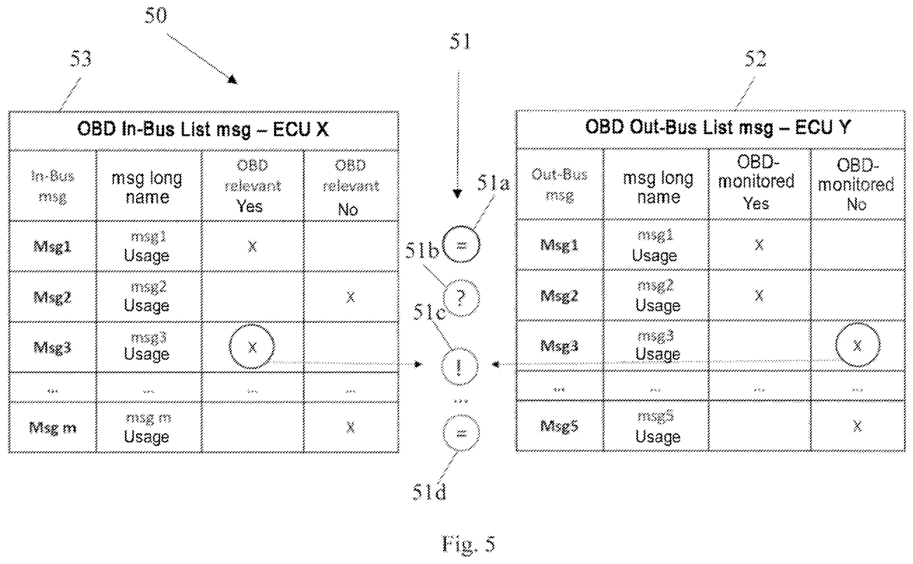

Further details and aspects are mentioned in conjunction with the examples described above or below. The exemplary embodiment shown in FIGS. 3a and 3b can have one or more optional additional features corresponding to one or more aspects mentioned in connection with the proposed design or with one or more exemplary embodiments described above (e.g. FIGS. 1-2) or below (e.g. FIGS. 4-5).

FIG. 4 shows an example 40 of a comparison 41 of OBD-relevance values determined according to the method with a reference list 43 for checking the consistency of the result determined according to the method. An input list 42 generated according to the method indicates whether or not the input signals from signal sources Sensor 1-Sensor m are potentially OBD-relevant. The reference list 43 indicates whether or not the signals of the same signal sources Sensor 1-Sensor m are labeled as OBD-verified according to existing data (e.g. historical documentation, developer knowledge).

In the example of the comparison step 41, the attribution of the input signals from signal source Sensor 1 and Sensor 2 is consistent, so that a reliable test result can be assumed. Comparison results 41a and 41b are therefore positive. In the reference list 43, signal source Sensor 3 is listed as not OBD-monitored, whereas the check according to the method indicates that the corresponding input signal is OBD-relevant. Therefore, a comparison result 41c is output as a warning signal 41c. In this case, the signal source Sensor 3 can be monitored, for example, in order to comply with regulations. In the fourth example of Sensor m, OBD monitoring is indicated in the reference list 43, but the method 10 comes to the conclusion that the corresponding input signal is not OBD-relevant. In this case, a comparison result 41d can be displayed that suggests a verification. However, this case is less critical, as in case of doubt only one OBD monitoring too many takes place, which although requiring resources has no negative effect on the monitoring of emissions-related functions. However, the result can be used to optimize the system, for example to avoid over-compliance of the OBD monitoring and thus to increase efficiency. For a correct result of the comparison 41, it is necessary for the elements of signal sources and signal targets to be identical (name and number).

Further details and aspects are mentioned in conjunction with the examples described above or below. The exemplary embodiments shown in FIG. 4 can have one or more optional additional features corresponding to one or more aspects mentioned in connection with the proposed design or with one or more exemplary embodiments described above (e.g. FIGS. 1-3b) or below (e.g. FIG. 5).

FIG. 5 shows an example 50 of a comparison 51 of OBD-relevant input signals with OBD information for corresponding output signals of an upstream control unit (e.g. whether the output signal is OBD-compliant). List 53 indicates which input signals of a first electronic control unit (ECU) X are classified as OBD-relevant. A further list 52 indicates which output signals of an additional control unit (ECU) Y are OBD-monitored. The additional control unit Y is positioned upstream of the first control unit X in the signal flow. Since in this case the output signals of the additional control unit Y correspond to the input signals of the first control unit X, if the verification according to the method is correct, the result of the comparison must be consistent (an OBD-relevant input signal must also be known as OBD-monitored when viewed as an output signal).

For the Msg1 and Msg_m input signals shown, the comparison 51 indicates consistent results 51a, 51d. For the input signals Msg2 and Msg3, the result of the comparison 51 is inconsistent. According to the check according to the method 10, from the point of view of the first control unit X, it is indicated that the input signal Msg2 is not OBD-relevant, but at the second control unit it is treated as OBD-monitored. In this case, a comparison result 51b is indicated, on the basis of which a verification can take place, which means e.g. that a system optimization is possible. In the case of input signal Msg3 on the other hand, this is indicated as potentially OBD-relevant, but the corresponding output signal at the other control unit Y is not monitored according to the OBD requirements. As a result, a warning signal 51c is output, which can, for example, prompt the OBD monitoring on the other control unit Y to be verified in order to obtain a consistent comparison result and thus increased certainty of the correct OBD attribution (e.g. to meet requirements of OBD specifications). For a correct result of the comparison 51, it is necessary that the elements of the lists received/sent between the two control units are identical (names/number), so that there is consistency.

Further details and aspects are mentioned in conjunction with the examples described above or below. The exemplary embodiment shown in FIG. 5 can have one or more optional additional features corresponding to one or more aspects mentioned in connection with the proposed design or with one or more exemplary embodiments described above (e.g. FIGS. 1-4) or below.

Examples relate to the verification and determination of OBD attributes by means of signal networks. The check can comprise a plurality of steps: on the basis of historical documentation (e.g. manually generated), OBD attributes can be pre-assigned in the signal network. Signal starting points can be defined in the signal network (Sources). Signal endpoints can be defined in the signal network (Targets). Connection paths between all sources and targets in the signal network can be checked (Connection Matrix). A BOOL-OR inheritance of the potential OBD relevance can be applied for all signals upstream for existing connections (from target to source) or a BOOL-AND inheritance of the OBD compliance for all signals downstream for existing connections (from source to target). A comparison of OBD attributes “Compliance” and “Relevance” can be made at critical nodes (Compliance Check).

Examples can also provide a computer program having a program code for executing one or more of the above methods when the computer program is executed on a computer or processor. Steps, operations or processes of various methods described above can be performed by programmed computers or processors. Examples can also include program storage devices, such as digital data storage media, which are readable by machines, processors or computers and can encode machine-executable, processor-executable or computer-executable programs of instructions. The instructions execute some or all of the steps of the above described methods or cause their execution. The program storage devices can comprise or be, for example, digital memories, magnetic storage media such as magnetic disks and magnetic tapes, hard disk drives, or optically readable digital data storage media. Other examples can also cover computers, processors or control units that are programmed to execute the steps of the methods described above, or (field-)programmable logic arrays ((F)PLAs) or (field-)programmable gate arrays ((F)PGAs), which are programmed to execute the steps of the methods described above.

A function block designated as a “means for . . . ”, which performs a specific function, may refer to a circuit that is designed to perform a specific function. Thus, a “means for something” can be implemented as a “means designed for or suitable for something”, e.g. a device or a circuit designed for or suitable for the respective task.

Functions of various elements shown in the figures including all function blocks designated as “means”, “means for providing a signal”, “means for generating a signal”, etc. can be implemented in the form of dedicated hardware, e.g. “a signal provider”, “a signal processing unit”, “a processor”, “a controller”, etc., as well as hardware capable of executing software in conjunction with the associated software. When provided by a processor the functions can be provided by a single dedicated processor, by a single jointly used processor, or by a plurality of individual processors, some of which or all of which can be used jointly. However, the term “processor” or “controller” is by no means limited exclusively to the execution of software-enabled hardware, but can comprise digital signal processor hardware (DSP hardware), a network processor, application-specific integrated circuit (ASIC), field programmable logic array (FPGA=Field Programmable Gate Array), Read Only Memory (ROM) for storing software, Random Access Memory (RAM) and non-volatile memory device (storage). Other hardware, conventional and/or customized, can also be included.

A block diagram can represent, for example, a more detailed circuit diagram which implements the principles of the disclosure. Similarly, a flow chart, a program flow diagram, a state transition diagram, a pseudo-code and the like can represent different processes, operations or steps which are essentially represented, for example, in computer-readable medium and thus executed by a computer or processor, regardless of whether such a computer or processor is explicitly shown. Methods disclosed in the description or in the patent claims can be implemented by a device which has a means for executing each one of the respective steps of these methods.

1.-8. (canceled)

9. A method for automatically checking, in an approval procedure for a vehicle, whether an input signal of a control unit for the vehicle is potentially relevant to on-board diagnostics, the method comprising:
using a signal network which represents a signal flow in the control unit, the signal network comprising the input signal and at least one on-board diagnostics-relevant output signal;
verifying whether a signal connection is present between the input signal and the at least one on-board diagnostics-relevant output signal; and
indicating that the input signal is potentially on-board diagnostics-relevant if the signal connection is present between the input signal and the at least one output signal.

10. The method as claimed in claim 9, wherein the input signal is a sensor signal that is applied to a signal input of the control unit.

11. The method as claimed in claim 9, wherein the input signal is a BUS signal that is applied to a signal input of the control unit.

12. The method as claimed in claim 9, wherein the signal network comprises a further input signal, and further comprising:
verifying whether a further signal connection is present between the further input signal and any of the at least one on-board diagnostics-relevant output signal; and
indicating that the further input signal is potentially on-board diagnostics-relevant if the further signal connection is present between the input signal and any of the at least one output signal.

13. The method as claimed in claim 9, further comprising using a connection matrix when verifying whether the signal connection is present between the input signal and the at least one on-board diagnostics-relevant output signal.

14. The method as claimed in claim 9, further comprising:
providing a pre-determined property of the input signal with regard to a relevance to on-board diagnostics of the input signal;
comparing the potentially on-board diagnostics-relevant input signal with the pre-determined property; and
outputting a warning signal if the potentially on-board diagnostics-relevant input signal does not match the pre-determined property.

15. The method as claimed in claim 14, wherein the input signal is a sensor signal that is applied to a signal input of the control unit.

16. The method as claimed in claim 14, wherein the input signal is a BUS signal that is applied to a signal input of the control unit.

17. The method as claimed in claim 14, further comprising using a connection matrix when verifying whether the signal connection is present between the input signal and the at least one on-board diagnostics-relevant output signal.

18. The method as claimed in claim 6, further comprising:
checking whether the input signal is sent from an additional control unit for the vehicle as an output signal;
automatically checking whether the output signal from the additional control unit is displayed as on-board diagnostics-monitored; and
outputting a warning signal if an on-board diagnostic property of the input signal and the output signal, as verified by both control units, are inconsistent.

19. The method as claimed in claim 18, wherein the input signal is a sensor signal that is applied to a signal input of the control unit.

20. The method as claimed in claim 18, wherein the input signal is a BUS signal that is applied to a signal input of the control unit.

21. The method as claimed in claim 18, further comprising using a connection matrix when verifying whether the signal connection is present between the input signal and the at least one on-board diagnostics-relevant output signal.

22. The method as claimed in claim 9, further comprising:
checking whether the input signal is sent from an additional control unit for the vehicle as an output signal;
automatically checking whether the output signal from the additional control unit is displayed as on-board diagnostics-monitored; and
outputting a warning signal if an on-board diagnostic property of the input signal and the output signal, as verified by both control units, are inconsistent.

23. The method as claimed in claim 22, wherein the input signal is a sensor signal that is applied to a signal input of the control unit.

24. The method as claimed in claim 22, wherein the input signal is a BUS signal that is applied to a signal input of the control unit.

25. The method as claimed in claim 22, further comprising using a connection matrix when verifying whether the signal connection is present between the input signal and the at least one on-board diagnostics-relevant output signal.

26. A non-transitory storage medium containing a computer program having a program code to carry out the method as claimed in claim 9 when the computer program is executed on a processor, a computer, or programmable hardware.
